(19) United States
(12) Patent Application Publication
(10) Pub. No.: US 2024/0222148 A1
(43) Pub. Date: Jul. 4, 2024

(54) AIRFLOW CONTROL SYSTEM AND AIRFLOW CONTROL METHOD

(71) Applicant: SEMES CO., LTD., Cheonan-si, Chungcheongnam-do (KR)

(72) Inventors: Ickkyun KIM, Cheonan-si (KR); Sang Yong EOM, Cheonan-si (KR); Cheol PARK, Cheonan-si (KR); Moon Hyung BAE, Cheonan-si (KR); Tae Young KIM, Cheonan-si (KR)

(73) Assignee: SEMES CO., LTD., Cheonan-si, Chungcheongnam-do (KR)

(21) Appl. No.: 18/395,487

(22) Filed: Dec. 23, 2023

(30) Foreign Application Priority Data
Dec. 28, 2022 (KR) 10-2022-0187730

(51) Int. Cl. H01L 21/67; H01L 21/677

(52) U.S. Cl. CPC H01L 21/67017; H01L 21/67098; H01L 21/6715; H01L 21/67161; H01L 21/67253; H01L 21/67766; G03F 7/162

(57) ABSTRACT

Provided is an airflow control system and airflow control method capable of preventing the inflow of foreign, the airflow control system including at least one grating panel mounted on a floor of a clean room and including a plurality of through holes, a semiconductor manufacturing equipment spaced apart from the grating panel by a gap space by using supports or legs, and including a fan mounted toward the grating panel, and a negative pressure preventer for preventing a negative pressure locally formed in the gap space due to a pressure difference between an outer downward airflow flowing along sides of the semiconductor manufacturing equipment and expelled to an outside through the through holes of the grating panel, and an inner downward airflow flowing from the semiconductor manufacturing equipment to the grating panel by the fan and expelled to the outside through the through holes of the grating panel.

### CROSS-REFERENCE TO RELATED PATENT APPLICATION

This application claims the benefit of Korean Patent Application No. 10-2022-0187730, filed on Dec. 28, 2022, in the Korean Intellectual Property Office, the disclosure of which is incorporated herein in its entirety by reference.

### BACKGROUND OF THE INVENTION

### 1. Field of the Invention

The present invention relates to an airflow control system and airflow control method and, more particularly, to an airflow control system and airflow control method capable of preventing the inflow of foreign substances by preventing a negative pressure locally formed under an equipment.

### 2. Description of the Related Art

In general, various processes such as cleaning, deposition, photolithography, etching, and ion implantation are performed to manufacture semiconductor devices. Photolithography is a process of forming a desired pattern on a substrate (or wafer). Photolithography may usually be connected to exposure and performed in a spinner local equipment for sequentially performing coating, exposure, and development.

The spinner local equipment may sequentially or selectively perform hydrophobization, coating, baking, and development.

The spinner local equipment forms a flow of air to the bottom of the equipment by form a downward airflow, and may expel the airflow to the outside of the equipment by using a fan mounted on the bottom surface of the equipment.

The airflow expelled to the outside of the equipment may be expelled to the outside of a clean room through floor-tile-shaped grating panels mounted on the floor of the clean room and including a plurality of through holes.

However, according to existing grating panels which also include the through holes below the equipment, a negative pressure may be formed in a gap space due to a pressure difference between an outer downward airflow flowing along sides of the equipment and expelled to the outside through the through holes of the grating panels, and an inner downward airflow flowing from the equipment to the grating panels by the fan and expelled to the outside through the through holes of the grating panels, and foreign substances may flow in from the outside of the equipment due to the negative pressure to contaminate the inside of the equipment.

### SUMMARY OF THE INVENTION

The present invention provides an airflow control system and airflow control method capable of preventing the contamination of an equipment and substrates due to the inflow of external foreign substances by fundamentally preventing the formation of a negative pressure in a gap space between the bottom of the equipment and a grating panel. However, the above description is an example, and the scope of the present invention is not limited thereto.

According to an aspect of the present invention, there is provided an airflow control system including at least one grating panel mounted on a floor of a clean room and including a plurality of through holes, a semiconductor manufacturing equipment spaced apart from the grating panel by a gap space by using supports or legs, and including a fan mounted toward the grating panel, and a negative pressure preventer for preventing a negative pressure locally formed in the gap space due to a pressure difference between an outer downward airflow flowing along sides of the semiconductor manufacturing equipment and expelled to an outside through the through holes of the grating panel, and an inner downward airflow flowing from the semiconductor manufacturing equipment to the grating panel by the fan and expelled to the outside through the through holes of the grating panel.

The negative pressure preventer may include a blocking plate mounted below the semiconductor manufacturing equipment to induce the inner downward airflow to one or both sides from the gap space, and mounted on an upper surface of the grating panel to block at least some of the through holes of the grating panel.

The negative pressure preventer may include a blocking frame mounted on an upper surface of the grating panel and including a plurality of through windows arranged in M rows and N columns, and a blocking cover covering at least some of the through windows.

The negative pressure preventer may include a fixed plate fixed to an upper surface of the grating panel, and a movable plate slidably mounted on the fixed plate so as to be widened or narrowed.

The negative pressure preventer may further include a movable plate driver for sliding the movable plate forward or backward.

The negative pressure preventer may include an aperture ratio adjustment plate slidably mounted on an upper surface of the grating panel and including openings aligned or misaligned with the through holes of the grating panel to adjust an aperture ratio of the through holes when sliding.

The negative pressure preventer may further include an aperture ratio adjustment plate driver for sliding the aperture ratio adjustment plate.

The negative pressure preventer may further include a pressure measurer for measuring a pressure of the gap space, and a controller for receiving a pressure signal from the pressure measurer and applying an aperture ratio control signal to the aperture ratio adjustment plate driver to adjust the aperture ratio of the through holes of the grating panel based on the pressure signal.

The airflow control system may further include an anemometer rotated forward or backward by a wind pressure to check whether a backflow has occurred in the gap space due to the negative pressure.

The airflow control system may further include a controller for receiving a wind speed signal from the anemometer and applying a negative pressure removal control signal to the negative pressure preventer based on the wind speed signal.

The negative pressure preventer may include an airflow blocking panel provided in the same size as the grating panel so as to be mounted instead of the grating panel on the floor of the clean room, and having a shape in which the through holes are closed.

The semiconductor manufacturing equipment may include an index module for transferring a plurality of substrates from a carrier storing the substrates, and a treating module including a plurality of process blocks for processing the transferred substrates.

The negative pressure preventer may be provided below a center of a bottom plate of the index module or the treating module, or directly below the fan mounted downward on the bottom plate of the index module or the treating module.

An airflow former for forming a downward airflow may be mounted on the index module or the treating module.

The index module may include an index frame, a load port mounted on the index frame to seat thereon the carrier storing the substrates, a guide rail mounted in the index frame, and an index robot moving along the guide rail to transfer the substrates.

The treating module may include coating blocks stacked on one another in one or more layers to perform a coating process on the substrates, and development blocks stacked on one another in one or more layers to perform a development process on the substrates.

Each of the coating blocks may include heat treatment chambers for performing a heat treatment process on the substrates, liquid treatment chambers for supplying a liquid onto the substrates to form a liquid layer, and a transfer chamber for transferring the substrates between the heat treatment chambers and the liquid treatment chambers.

According to another aspect of the present invention, there is provided an airflow control method including (a) forming an inner downward airflow to be expelled to an outside through a plurality of through holes of at least one grating panel, by using a fan toward a gap space between the grating panel mounted on a floor of a clean room and including the through holes, and a semiconductor manufacturing equipment spaced apart from the grating panel, (b) measuring a pressure of the gap space by using a pressure measurer, and (c) applying a negative pressure removal control signal to a negative pressure preventer when it is determined, based on a measured pressure signal, that a negative pressure is formed in the gap space.

In step (c), when it is determined, based on the measured pressure signal, that the negative pressure is formed in the gap space, an aperture ratio adjustment plate including openings aligned or misaligned with the through holes may be slid using an aperture ratio adjustment plate driver.

According to another aspect of the present invention, there is provided an airflow control system including at least one grating panel mounted on a floor of a clean room and including a plurality of through holes, a semiconductor manufacturing equipment spaced apart from the grating panel by a gap space by using supports or legs, and including a fan mounted toward the grating panel, and a negative pressure preventer for preventing a negative pressure locally formed in the gap space due to a pressure difference between an outer downward airflow flowing along sides of the semiconductor manufacturing equipment and expelled to an outside through the through holes of the grating panel, and an inner downward airflow flowing from the semiconductor manufacturing equipment to the grating panel by the fan and expelled to the outside through the through holes of the grating panel, wherein the negative pressure preventer includes a blocking plate mounted below the semiconductor manufacturing equipment to induce the inner downward airflow to one or both sides from the gap space, and mounted on an upper surface of the grating panel to block at least some of the through holes of the grating panel, or wherein the negative pressure preventer includes an aperture ratio adjustment plate slidably mounted on an upper surface of the grating panel and including openings aligned or misaligned with the through holes of the grating panel to adjust an aperture ratio of the through holes when sliding, an aperture ratio adjustment plate driver for sliding the aperture ratio adjustment plate, a pressure measurer for measuring a pressure of the gap space, and a controller for receiving a pressure signal from the pressure measurer and applying an aperture ratio control signal to the aperture ratio adjustment plate driver to adjust the aperture ratio of the through holes of the grating panel based on the pressure signal, wherein the semiconductor manufacturing equipment includes an index module for transferring a plurality of substrates from a carrier storing the substrates, and a treating module including a plurality of process blocks for processing the transferred substrates, and wherein the negative pressure preventer is provided below a center of a bottom plate of the index module or the treating module, or directly below the fan mounted downward on the bottom plate of the index module or the treating module.

### BRIEF DESCRIPTION OF THE DRAWINGS

The above and other features and advantages of the present invention will become more apparent by describing in detail embodiments thereof with reference to the attached drawings in which:

FIG. 1 is a perspective view of a semiconductor manufacturing equipment according to some embodiments of the present invention;

FIG. 2 is a side cross-sectional view of the semiconductor manufacturing equipment of FIG. 1;

FIG. 3 is a plan view of the semiconductor manufacturing equipment of FIG. 1;

FIGS. 4 to 10 are conceptual views of airflow control systems applicable to the semiconductor manufacturing equipment of FIG. 1, according to various embodiments of the present invention; and

FIG. 11 is a flowchart of an airflow control method according to some embodiments of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

The terminology used herein is for the purpose of describing particular embodiments and is not intended to limit the invention. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, components, and/or groups thereof, but do not preclude the presence or addition of one or more other features, integers, steps, operations, elements, components, and/or groups thereof.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

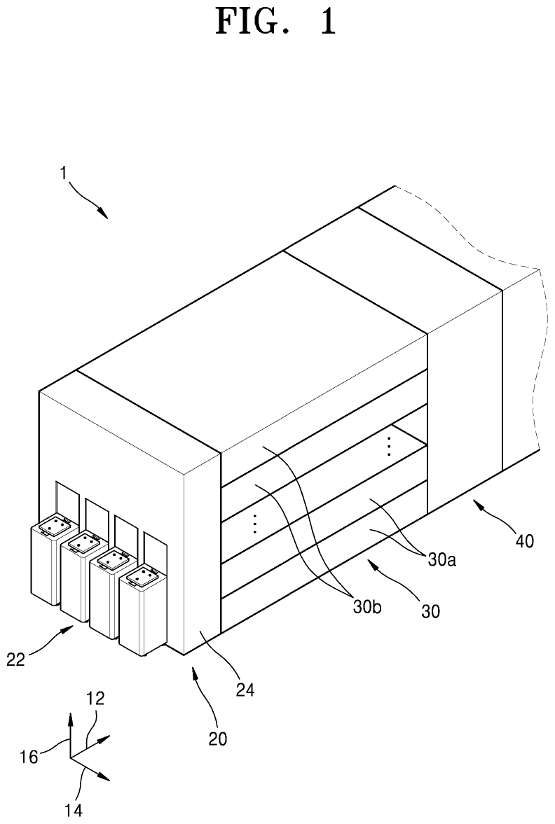

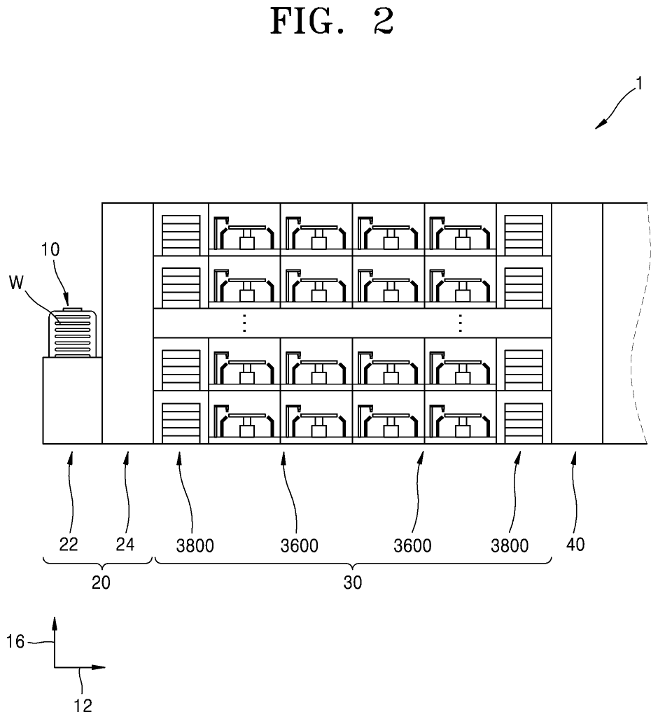

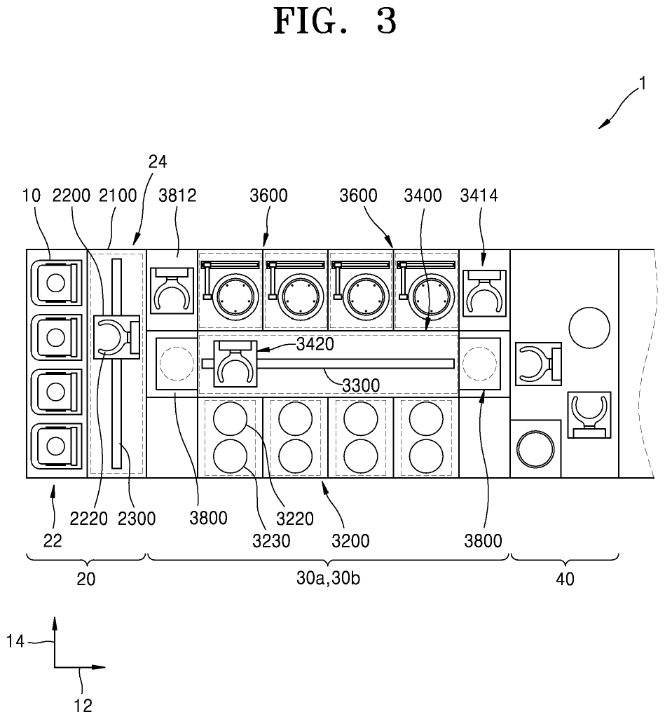

FIG. 1 is a perspective view of a semiconductor manufacturing equipment 1 according to some embodiments of the present invention, FIG. 2 is a side cross-sectional view of the semiconductor manufacturing equipment 1 of FIG. 1, and FIG. 3 is a plan view of the semiconductor manufacturing equipment 1 of FIG. 1.

As shown in FIGS. 1 to 3, the semiconductor manufacturing equipment 1 according to some embodiments of the present invention includes an index module 20, a treating module 30, and an interface module 40. According to an embodiment, the index module 20, the treating module 30, and the interface module 40 are sequentially arranged in a row. Hereinafter, a direction in which the index module 20, the treating module 30, and the interface module 40 are arranged is referred to as an X-axis direction 12, a direction perpendicular to the X-axis direction 12 when viewed from above is referred to as a Y-axis direction 14, and a direction perpendicular to both the X-axis direction 12 and the Y-axis direction 14 is referred to as a Z-axis direction 16.

The index module 20 transfers substrates W from a carrier 10 storing the substrates W to the treating module 30, and stores the substrates W in the carrier 10 after the substrates W are processed. A longitudinal direction of the index module 20 is provided along the Y-axis direction 14. The index module 20 includes a load port 22 and an index frame 24. The load port 22 is positioned opposite to the treating module 30 with respect to the index frame 24. The carrier 10 storing the substrates W is placed on the load port 22. The load port 22 may include a plurality of load ports 22, and the plurality of load ports 22 may be arranged along the Y-axis direction 14.

The carrier 10 may use a sealed carrier 10 such as a front opening unified pod (FOUP). The carrier 10 may be placed on the load port 22 by an operator or a transfer means (not shown) such as an overhead transfer, an overhead conveyor, or an automated guided vehicle.

An index robot 2200 is provided in the index frame 24. A guide rail 2300, a longitudinal direction of which is provided in the Y-axis direction 14, may be provided along the index frame 24, and the index robot 2200 may be provided to move on the guide rail 2300. The index robot 2200 may include a hand 2220 on which the substrate W is placed, and the hand 2220 may be provided to move forward and backward, rotate about the Z-axis direction 16 as an axis of rotation, and move along the Z-axis direction 16.

The treating module 30 performs a coating process and a development process on the substrates W. The treating module 30 includes coating blocks 30a and development blocks 30b. The coating blocks 30a perform a coating process on the substrates W, and the development blocks 30b perform a development process on the substrates W. A plurality of coating blocks 30a are stacked on one another. A plurality of development blocks 30b are stacked on one another. According to the embodiment of FIG. 1, two coating blocks 30a are provided and two development blocks 30b are provided. The coating blocks 30a may be disposed under the development blocks 30b. According to an example, the two coating blocks 30a may perform the same process and provided in the same structure. The two development blocks 30b may also perform the same process and provided in the same structure.

Referring to FIG. 3, each coating block 30a includes heat treatment chambers 3200, a transfer chamber 3400, liquid treatment chambers 3600, and buffer chambers 3800. The heat treatment chambers 3200 perform a heat treatment process on the substrates W. The heat treatment process may include a cooling process and a heating process. The liquid treatment chambers 3600 supply a liquid onto the substrates W to form a liquid layer. The liquid layer may be a photoresist layer or an anti-reflective layer. The transfer chamber 3400 transfers the substrates W between the heat treatment chambers 3200 and the liquid treatment chambers 3600 in the coating block 30a.

The transfer chamber 3400 is provided to have a longitudinal direction parallel to the X-axis direction 12. A transfer unit 3420 is provided in the transfer chamber 3400. The transfer unit 3420 transfers the substrates W between the heat treatment chambers 3200, the liquid treatment chambers 3600, and the buffer chambers 3800. According to an example, the transfer unit 3420 may include a hand on which the substrate W is placed, and the hand may be provided to move forward and backward, rotate about the Z-axis direction 16 as an axis of rotation, and move along the Z-axis direction 16. A guide rail 3300 having a longitudinal direction parallel to the X-axis direction 12 may be provided in the transfer chamber 3400, and the transfer unit 3420 may be provided to move on the guide rail 3300.

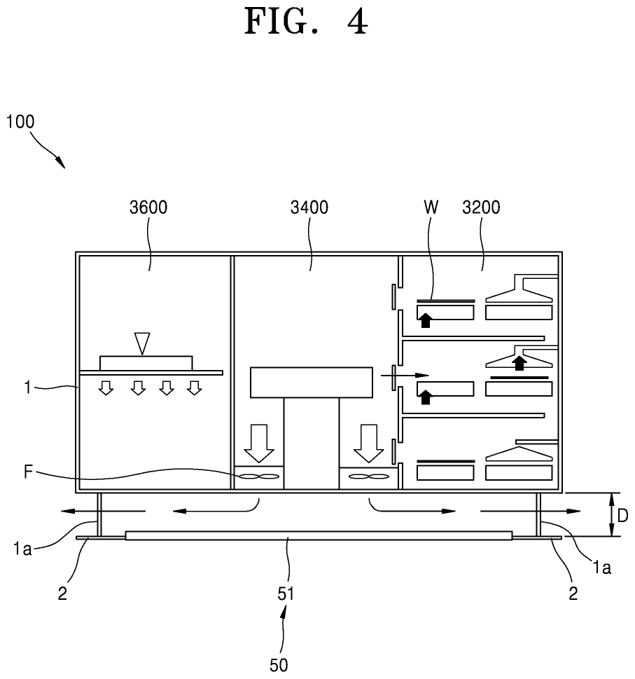

FIGS. 4 to 10 are conceptual views of airflow control systems applicable to the semiconductor manufacturing equipment 1 of FIG. 1, according to various embodiments of the present invention.

FIG. 4 is a conceptual view of an airflow control system 100 according to some embodiments of the present invention.

As shown in FIG. 4, the airflow control system 100 according to some embodiments of the present invention may include at least one grating panel 2 mounted on the floor of a clean room and including a plurality of through holes 2a, the semiconductor manufacturing equipment 1 spaced apart from the grating panel 2 by a gap space D by using supports 1a or legs, and including a fan F mounted toward the grating panel 2, and a negative pressure preventer 50 for preventing a negative pressure locally formed in the gap space D due to a pressure difference between an outer downward airflow flowing along sides of the semiconductor manufacturing equipment 1 and expelled to the outside through the through holes 2a of the grating panel 2, and an inner downward airflow flowing from the semiconductor manufacturing equipment 1 to the grating panel 2 by the fan F and expelled to the outside through the through holes 2a of the grating panel 2.

The negative pressure preventer 50 may include a blocking plate 51 mounted below the semiconductor manufacturing equipment 1 to induce the inner downward airflow to one or both sides from the gap space D, and mounted on an upper surface of the grating panel 2 to block at least some of the through holes 2a of the grating panel 2.

Herein, the blocking plate 51 may be mounted on the upper surface of the grating panel 2 or mounted instead of the grating panel 2 on a frame of the grating panel 2 by removing the grating panel 2.

Therefore, because the blocking plate 51 blocks at least some of the through holes 2a of the grating panel 2, the inner downward airflow may be partially blocked and the airflow may be induced to the sides at the same time, thereby preventing the formation of a relative airflow difference and a negative pressure. The blocking plate 51 may also block a backflow through the through holes 2a of the grating panel 2.

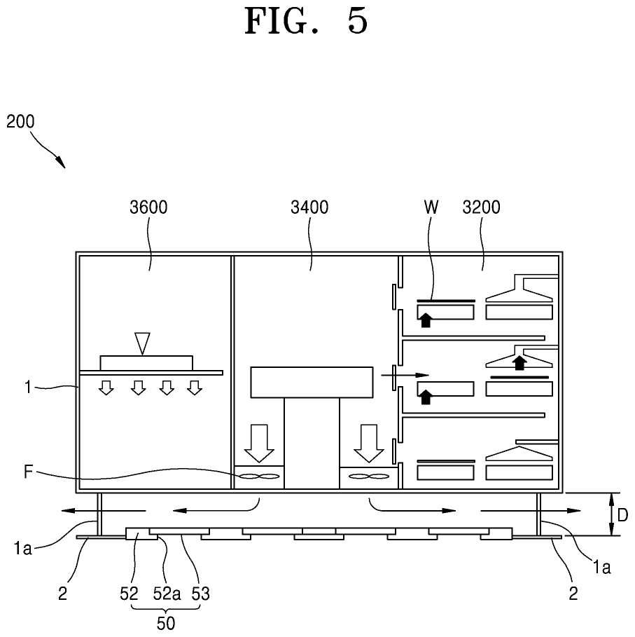

FIG. 5 is a conceptual view of an airflow control system 200 according to other embodiments of the present invention.

As shown in FIG. 5, the negative pressure preventer 50 of the airflow control system 200 according to other embodiments of the present invention may include a blocking frame 52 mounted on the upper surface of the grating panel 2 and including a plurality of through windows 52a arranged in M rows and N columns, and a blocking cover 53 covering at least some of the through windows 52a.

Therefore, an environment-specific configuration may be enabled by selectively seating the blocking cover 53 on the through windows 52a of the blocking frame 52 to prevent the formation of a negative pressure in the gap space D based on various manufacturing environments.

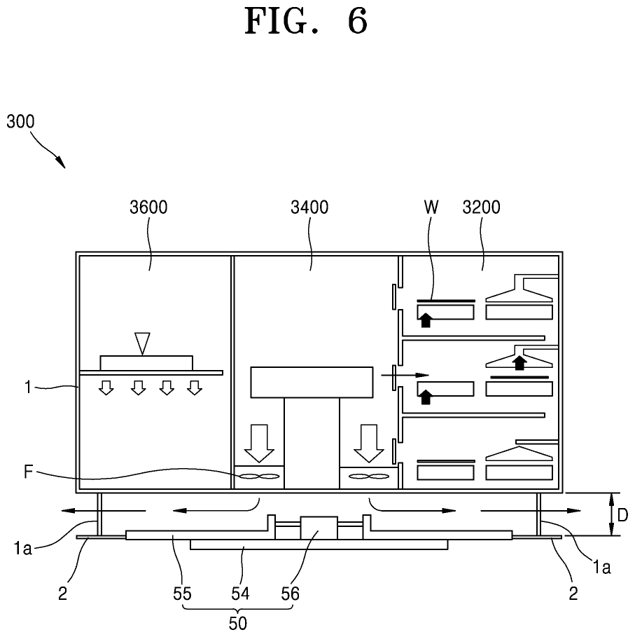

FIG. 6 is a conceptual view of an airflow control system 300 according to other embodiments of the present invention.

As shown in FIG. 6, the negative pressure preventer 50 of the airflow control system 300 according to other embodiments of the present invention may include a fixed plate 54 fixed to the upper surface of the grating panel 2, a movable plate 55 slidably mounted on the fixed plate 54 so as to be widened or narrowed, and a movable plate driver 56 for sliding the movable plate 55 forward or backward.

Therefore, the movable plate 55 may be widened or narrowed and adaptively used within a range where a negative pressure is not formed, by sliding the movable plate 55 forward or backward by using the movable plate driver 56 to prevent the formation of a negative pressure in the gap space D based on various manufacturing environments.

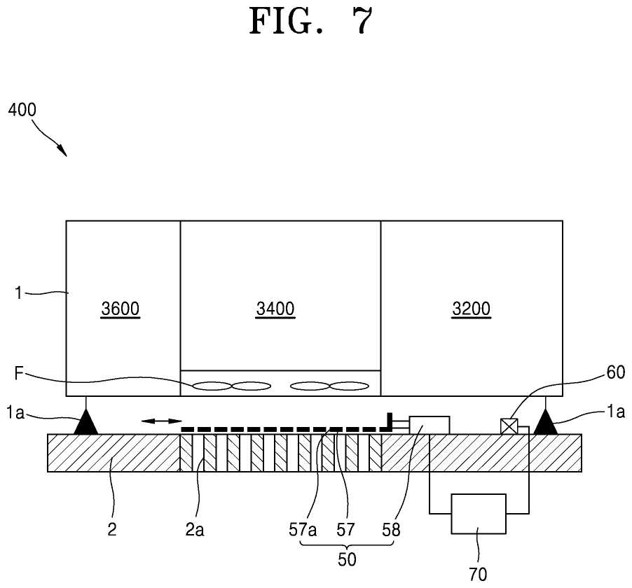

FIG. 7 is a conceptual view of an airflow control system 400 according to other embodiments of the present invention.

As shown in FIG. 7, the negative pressure preventer 50 of the airflow control system 400 according to other embodiments of the present invention may include an aperture ratio adjustment plate 57 slidably mounted on the upper surface of the grating panel 2 and including openings 57a aligned or misaligned with the through holes 2a of the grating panel 2 to adjust an aperture ratio of the through holes 2a when sliding, an aperture ratio adjustment plate driver 58 for sliding the aperture ratio adjustment plate 57, a pressure measurer 60 for measuring a pressure of the gap space D, and a controller 70 for receiving a pressure signal from the pressure measurer 60 and applying an aperture ratio control signal to the aperture ratio adjustment plate driver 58 to adjust the aperture ratio of the through holes 2a of the grating panel 2 based on the pressure signal.

Therefore, to prevent the formation of a negative pressure in the gap space D based on various manufacturing environments, the pressure measurer 60 may measure the pressure of the gap space D, the controller 70 may apply the aperture ratio control signal to the aperture ratio adjustment plate driver 58 to adjust the aperture ratio of the through holes 2a of the grating panel 2 based on the pressure signal, and the aperture ratio adjustment plate 57 may be slid to align or misalign the openings 57a with the through holes 2a.

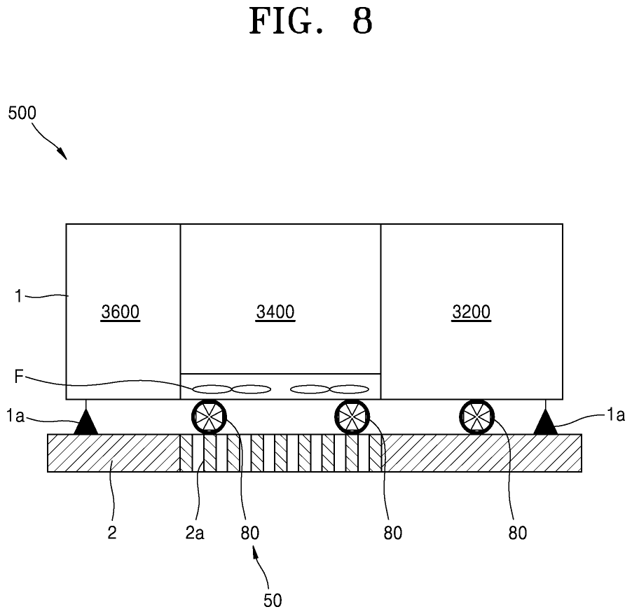

FIG. 8 is a conceptual view of an airflow control system 500 according to other embodiments of the present invention.

As shown in FIG. 8, the negative pressure preventer 50 of the airflow control system 500 according to other embodiments of the present invention may include an anemometer 80 rotated forward or backward by a wind pressure to check whether a backflow has occurred in the gap space D due to a negative pressure.

Therefore, a user may take measures to prevent the formation of a negative pressure by checking a rotation direction, a rotation speed, or the like of the anemometer 80 with eyes.

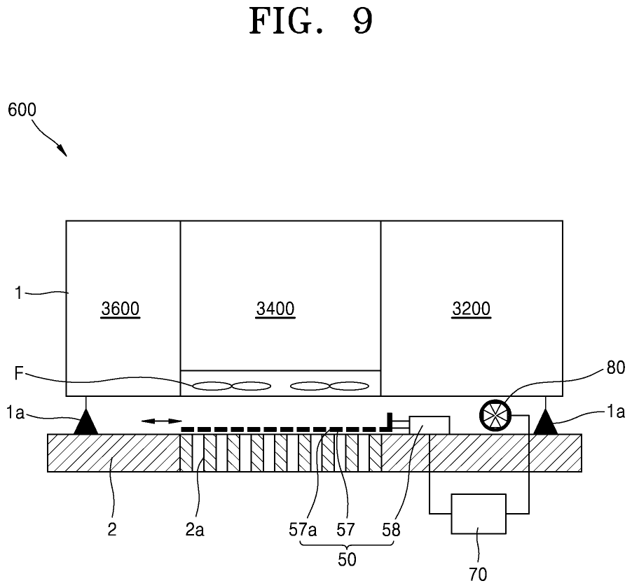

FIG. 9 is a conceptual view of an airflow control system 600 according to other embodiments of the present invention.

As shown in FIG. 9, the negative pressure preventer 50 of the airflow control system 600 according to other embodiments of the present invention may include an aperture ratio adjustment plate 57 slidably mounted on the upper surface of the grating panel 2 and including openings 57a aligned or misaligned with the through holes 2a of the grating panel 2 to adjust an aperture ratio of the through holes 2a when sliding, an aperture ratio adjustment plate driver 58 for sliding the aperture ratio adjustment plate 57, an anemometer 80 rotated forward or backward by a wind pressure to check whether a backflow has occurred in the gap space D due to a negative pressure, and a controller 70 for receiving a wind speed signal from the anemometer 80 and applying a negative pressure removal control signal to the negative pressure preventer 50 based on the wind speed signal.

Therefore, to prevent the formation of a negative pressure in the gap space D based on various manufacturing environments, the anemometer 80 may measure the pressure of the gap space D, the controller 70 may apply the aperture ratio control signal to the aperture ratio adjustment plate driver 58 to adjust the aperture ratio of the through holes 2a of the grating panel 2 based on the pressure signal, and the aperture ratio adjustment plate 57 may be slid to align or misalign the openings 57a with the through holes 2a.

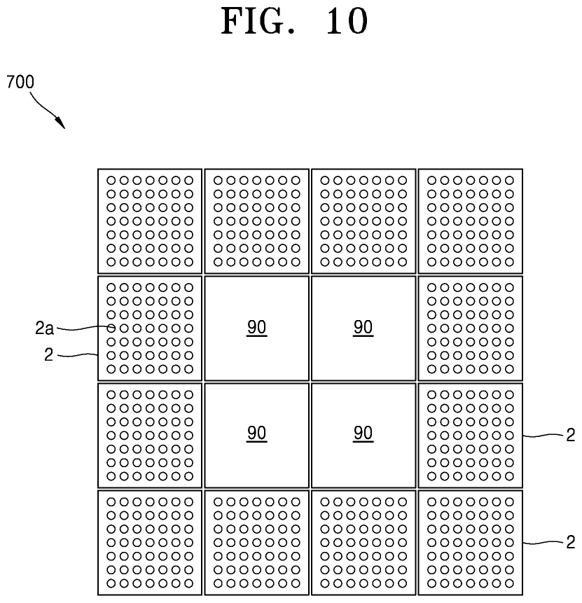

As shown in FIG. 10, the negative pressure preventer 50 of an airflow control system 700 according to other embodiments of the present invention may include airflow blocking panels 90 provided in the same size as the grating panels 2 so as to be mounted instead of the grating panels 2 on the floor of the clean room, and having a shape in which the through holes 2a are closed.

Therefore, the formation of a negative pressure may be fundamentally prevented by replacing some of the grating panels 2 mounted near a location where a negative pressure is formed, with the airflow blocking panels 90 to block the through holes 2a.

The negative pressure preventer 50 may be mounted where a negative pressure occurs frequently, and may be provided below the center of a bottom plate of the index module 20 or the treating module 30, or directly below the fan F mounted downward on the bottom plate of the index module 20 or the treating module 30.

Herein, an airflow former for forming a downward airflow, i.e., the fan F, may be mounted on the index module 20 or the treating module 30.

Accordingly, the contamination of the equipment 1 and the substrates W due to the inflow of external foreign substances by fundamentally preventing the formation of a negative pressure in the gap space D between the bottom of the equipment 1 and the grating panels 2.

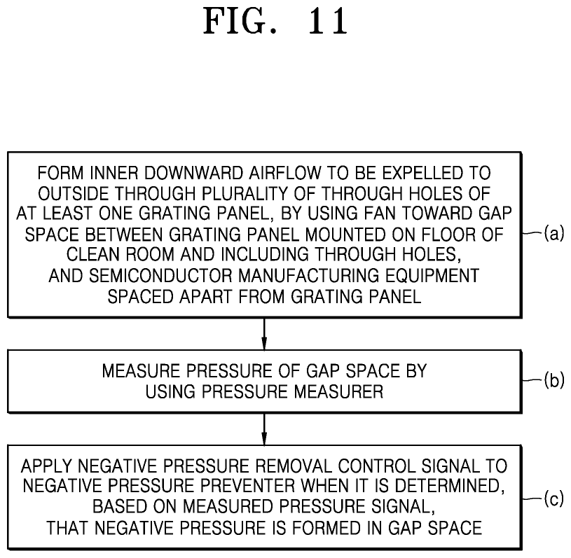

FIG. 11 is a flowchart of an airflow control method according to some embodiments of the present invention.

As shown in FIG. 11, the airflow control method according to some embodiments of the present invention may include (a) forming an inner downward airflow to be expelled to the outside through a plurality of through holes 2a of at least one grating panel 2, by using the fan F toward the gap space D between the grating panel 2 mounted on the floor of a clean room and including the through holes 2a, and the semiconductor manufacturing equipment 1 spaced apart from the grating panel 2, (b) measuring a pressure of the gap space D by using the pressure measurer 60, and (c) applying a negative pressure removal control signal to the negative pressure preventer 50 when it is determined, based on a measured pressure signal, that a negative pressure is formed in the gap space D.

In step (c), when it is determined, based on the measured pressure signal, that the negative pressure is formed in the gap space D, the aperture ratio adjustment plate 57 including the openings 57a aligned or misaligned with the through holes 2a may be slid using the aperture ratio adjustment plate driver 58.

According to the afore-described embodiments of the present invention, the contamination of an equipment and substrates due to the inflow of external foreign substances may be prevented by fundamentally preventing the formation of a negative pressure in a gap space between the bottom of the equipment 1 and a grating panel. However, the scope of the present invention is not limited to the above effect.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. An airflow control system comprising:
at least one grating panel mounted on a floor of a clean room and comprising a plurality of through holes;
a semiconductor manufacturing equipment spaced apart from the grating panel by a gap space by using supports or legs, and comprising a fan mounted toward the grating panel; and
a negative pressure preventer for preventing a negative pressure locally formed in the gap space due to a pressure difference between an outer downward airflow flowing along sides of the semiconductor manufacturing equipment and expelled to an outside through the through holes of the grating panel, and an inner downward airflow flowing from the semiconductor manufacturing equipment to the grating panel by the fan and expelled to the outside through the through holes of the grating panel.

2. The airflow control system of claim 1, wherein the negative pressure preventer comprises a blocking plate mounted below the semiconductor manufacturing equipment to induce the inner downward airflow to one or both sides from the gap space, and mounted on an upper surface of the grating panel to block at least some of the through holes of the grating panel.

3. The airflow control system of claim 1, wherein the negative pressure preventer comprises:
a blocking frame mounted on an upper surface of the grating panel and comprising a plurality of through windows arranged in M rows and N columns; and
a blocking cover covering at least some of the through windows.

4. The airflow control system of claim 1, wherein the negative pressure preventer comprises:
a fixed plate fixed to an upper surface of the grating panel; and
a movable plate slidably mounted on the fixed plate so as to be widened or narrowed.

5. The airflow control system of claim 4, wherein the negative pressure preventer further comprises a movable plate driver for sliding the movable plate forward or backward.

6. The airflow control system of claim 1, wherein the negative pressure preventer comprises an aperture ratio adjustment plate slidably mounted on an upper surface of the grating panel and comprising openings aligned or misaligned with the through holes of the grating panel to adjust an aperture ratio of the through holes when sliding.

7. The airflow control system of claim 6, wherein the negative pressure preventer further comprises an aperture ratio adjustment plate driver for sliding the aperture ratio adjustment plate.

8. The airflow control system of claim 7, wherein the negative pressure preventer further comprises:
a pressure measurer for measuring a pressure of the gap space; and
a controller for receiving a pressure signal from the pressure measurer and applying an aperture ratio control signal to the aperture ratio adjustment plate driver to adjust the aperture ratio of the through holes of the grating panel based on the pressure signal.

9. The airflow control system of claim 1, further comprising an anemometer rotated forward or backward by a wind pressure to check whether a backflow has occurred in the gap space due to the negative pressure.

10. The airflow control system of claim 9, further comprising a controller for receiving a wind speed signal from the anemometer and applying a negative pressure removal control signal to the negative pressure preventer based on the wind speed signal.

11. The airflow control system of claim 1, wherein the negative pressure preventer comprises an airflow blocking panel provided in the same size as the grating panel so as to be mounted instead of the grating panel on the floor of the clean room, and having a shape in which the through holes are closed.

12. The airflow control system of claim 1, wherein the semiconductor manufacturing equipment comprises:
an index module for transferring a plurality of substrates from a carrier storing the substrates; and
a treating module comprising a plurality of process blocks for processing the transferred substrates.

13. The airflow control system of claim 12, wherein the negative pressure preventer is provided below a center of a bottom plate of the index module or the treating module, or directly below the fan mounted downward on the bottom plate of the index module or the treating module.

14. The airflow control system of claim 12, wherein an airflow former for forming a downward airflow is mounted on the index module or the treating module.

15. The airflow control system of claim 12, wherein the index module comprises:
an index frame;
a load port mounted on the index frame to seat thereon the carrier storing the substrates;
a guide rail mounted in the index frame; and
an index robot moving along the guide rail to transfer the substrates.

16. The airflow control system of claim 12, wherein the treating module comprises:
coating blocks stacked on one another in one or more layers to perform a coating process on the substrates; and
development blocks stacked on one another in one or more layers to perform a development process on the substrates.

17. The airflow control system of claim 16, wherein each of the coating blocks comprises:
heat treatment chambers for performing a heat treatment process on the substrates;
liquid treatment chambers for supplying a liquid onto the substrates to form a liquid layer; and
a transfer chamber for transferring the substrates between the heat treatment chambers and the liquid treatment chambers.

18. An airflow control method comprising:
(a) forming an inner downward airflow to be expelled to an outside through a plurality of through holes of at least one grating panel, by using a fan toward a gap space between the grating panel mounted on a floor of a clean room and comprising the through holes, and a semiconductor manufacturing equipment spaced apart from the grating panel;
(b) measuring a pressure of the gap space by using a pressure measurer; and
(c) applying a negative pressure removal control signal to a negative pressure preventer when it is determined, based on a measured pressure signal, that a negative pressure is formed in the gap space.

19. The airflow control method of claim 18, wherein, in step (c), when it is determined, based on the measured pressure signal, that the negative pressure is formed in the gap space, an aperture ratio adjustment plate comprising openings aligned or misaligned with the through holes is slid using an aperture ratio adjustment plate driver.

20. An airflow control system comprising:
at least one grating panel mounted on a floor of a clean room and comprising a plurality of through holes;
a semiconductor manufacturing equipment spaced apart from the grating panel by a gap space by using supports or legs, and comprising a fan mounted toward the grating panel; and
a negative pressure preventer for preventing a negative pressure locally formed in the gap space due to a pressure difference between an outer downward airflow flowing along sides of the semiconductor manufacturing equipment and expelled to an outside through the through holes of the grating panel, and an inner downward airflow flowing from the semiconductor manufacturing equipment to the grating panel by the fan and expelled to the outside through the through holes of the grating panel,
wherein the negative pressure preventer comprises a blocking plate mounted below the semiconductor manufacturing equipment to induce the inner downward airflow to one or both sides from the gap space, and mounted on an upper surface of the grating panel to block at least some of the through holes of the grating panel, or
wherein the negative pressure preventer comprises:
an aperture ratio adjustment plate slidably mounted on an upper surface of the grating panel and comprising openings aligned or misaligned with the through holes of the grating panel to adjust an aperture ratio of the through holes when sliding;
an aperture ratio adjustment plate driver for sliding the aperture ratio adjustment plate;
a pressure measurer for measuring a pressure of the gap space; and
a controller for receiving a pressure signal from the pressure measurer and applying an aperture ratio control signal to the aperture ratio adjustment plate driver to adjust the aperture ratio of the through holes of the grating panel based on the pressure signal,
wherein the semiconductor manufacturing equipment comprises:
an index module for transferring a plurality of substrates from a carrier storing the substrates; and
a treating module comprising a plurality of process blocks for processing the transferred substrates, and
wherein the negative pressure preventer is provided below a center of a bottom plate of the index module or the treating module, or directly below the fan mounted downward on the bottom plate of the index module or the treating module.
